(19) United States
(12) Patent Application Publication
(10) Pub. No.: US 2016/0042923 A1
(43) Pub. Date: Feb. 11, 2016

(54) PLASMA DEVICE

(71) Applicants: Kee Won SUH, Suwon-si (KR); ALLIED TECHFINDERS CO., LTD., Suwon-si (KR)

(72) Inventor: Kee Won SUH, Suwon-si (KR)

(73) Assignee: ALLIED TECHFINDERS CO., LTD., Suwon-si (KR)

(21) Appl. No.: 14/820,178

(22) Filed: Aug. 6, 2015

(30) Foreign Application Priority Data
Aug. 6, 2014 (KR) 10-2014-0100971
Aug. 14, 2014 (KR) 10-2014-0105909

(51) Int. Cl. H01J 37/32

(52) U.S. Cl. CPC H01J 37/32522; H01J 37/32669; H01J 37/32733; H01J 37/32449; H01J 2237/002; H01J 2237/3323

(57) ABSTRACT

A plasma device is proposed, the plasma device including: a chamber configured to accommodate a processed article; a plasma source configured to generate a plasma applied to the processed article accommodated in the chamber; a chuck unit configured to support the processed article accommodated in the chamber; and a cooling channel formed inside the chamber to allow flowing cooling water.

### CROSS-REFERENCE TO RELATED APPLICATION(S)

This application claims the benefit under 35 U.S.C. §119 (a) of Korean Patent Applications No. 10-2014-0105909, filed on Aug. 14, 2014, and Korean Patent Applications No. 10-2014-0100971, filed on Aug. 6, 2014 in the Korean Intellectual Property Office, the entire disclosure of which are incorporated by reference for all purposes.

### BACKGROUND

1. Field

The teachings in accordance with the exemplary embodiments of this present disclosure generally relate to a plasma device configured to process wafer and glass substrate for LCD using plasma devices.

2. Description of Related Art

Plasma is used in surface treatment technology forming a fine pattern on a surface of a process article such as wafer or glass substrate. Various plasma sources generating the plasma have been developed in response to fine line spacing pitch or LCD size.

Representative methods of plasma sources may include a CCP (Capacitively Coupled Plasma) source of parallel planar surface plasma type, and an ICP (Inductively Coupled Plasma) source employing an antenna coil that couples RF (Radio Frequency) energy into a working gas in a vacuum chamber.

The former (CCP) has been primarily developed by TEL (Tokyo Electron) of Japan, and by LRC (Lam Research) of USA, and the latter (ICP) has been largely developed by AMT (Applied Materials) and LRC of USA.

The ICP method may be advantageous in generating plasma at a low pressure and good fine circuit responsiveness due to excellent plasma density, while the ICP method suffers from disadvantages of decreased uniform plasma resultant from structural problems.

Although the CCP method may be advantageous in generating uniform plasma, the CCP method is disadvantageous because wafer or glass substrate, which is a processed article, is directly affected by electromagnetic field to inflict damage to fine pattern formation of the processed article. On top of that, the CCP source has a density relatively lower than that of ICP source to make the line spacing pitch narrower when processing the wafer to the disadvantage of pattern formation.

Furthermore, a high power may be applied to a broader region (7th generation and 8th generation) when processing a glass substrate, to make it difficult to transfer a uniform power to electrodes and to provide a greater damage to the processed article and to the device due to high power.

### SUMMARY

In one general aspect, there is provided a plasma device, a chamber configured to accommodate a processed article;

a plasma source configured to generate a plasma applied to the processed article accommodated in the chamber; a chuck unit configured to support the processed article accommodated in the chamber; and a cooling channel formed inside the chamber to allow flowing cooling water.

Preferably, but not necessarily, a mounting surface configured to mount the processed article on the chuck unit may be provided with a fine space naturally formed by a surface roughness, where the fine space is filled with thermal conduction gas configured to conduct heat between the processed article and the chuck unit.

Preferably, but not necessarily, the chuck unit may be provided with an electrode configured to apply electromagnetic force or an RF power source, one side of the electrode is grounded to a chamber and the other side of the electrode is rotatably connected to the chuck unit, and the other side of the electrode is connected with a power source for applying the electromagnetic force or the RF power source.

Preferably, but not necessarily, the chamber of the plasma device may include a transportation unit configured to accommodate a plasma-processed first substrate.

Preferably, but not necessarily, the transportation unit may be plasma-processed in the chamber with the first substrate.

The plasma device according to the exemplary embodiments of the present disclosure has an advantageous effect in that cooling water can be supplied in an ejection method in order to prevent a processed article from being twisted by thermal strain during cooling of the processed article, whereby the processed article can be evenly cooled.

Another advantage is that a surface opposite to a processed article in a chuck unit may be formed with surface roughness of a predetermined scope by cutting work to provide a fine space to be used as a thermal conduction gas channel whereby the thermal conduction gas can be evenly filled between the processed article and the chuck unit.

Still another advantage is that a fine space formed by surface roughness in comparison with the conventional method of artificially forming a lead or a gap can be provided at an area configured to evenly cover an entire processed article, whereby the entire processed article can be evenly cooled.

Still another advantage is that a first substrate of a size smaller than standard required by a chamber can be plasma-processed using a transportation unit.

Still further advantage is that, although a position of a substrate may be twisted in the course of the thermal conduction gas being supplied between the substrate and the transportation unit, the twist can be prevented by a first clamp configured to apply a pressure to the substrate toward the transportation unit.

Still further advantage is that a first clamp may be made of same material as that of the substrate in order to decrease a phenomenon where a deposition layer formed on the substrate is torn off by plasma processing along with breakaway of the first clamp.

Still further advantage is that the transportation unit may be provided with a second carrier configured to guide a mounting position of the substrate to allow the substrate to be positioned at an area of the thermal conduction gas being discharged, and a height of the second carrier may be same as that of the substrate, whereby the phenomenon of the deposition layer of the substrate being torn apart can be reduced in the course of the substrate being departed from the transportation unit, the effect of which can be further enhanced by making the material of the second carrier same as that of the substrate, and when it is difficult to make the material of the second carrier same as that of the substrate, an edge ring having a material same as that of the substrate may be inserted into an insertion hole inserted by the substrate.

Still further advantage is that an area mounted by the substrate at the first carrier may be divided into an edge area and a center area, where surface roughness of the edge area is made to be lower than that of the center area to thereby prevent the thermal conduction gas from deviating from roughness area.

### BRIEF DESCRIPTION OF DRAWINGS

FIG. 1 is a schematic cross-sectional view illustrating a plasma device according to the present disclosure.

FIG. 2 is a schematic view illustrating a plasma device of FIG. 1.

FIG. 3 is a schematic view illustrating a cooling channel constituting a plasma device according to the present disclosure.

FIG. 4 is a schematic view illustrating a cooling channel according to another exemplary embodiment of the present disclosure.

FIG. 5 is a graph illustrating a temperature of a processed article according to the present disclosure.

FIG. 6 is a schematic view illustrating a guide unit according to the present disclosure.

FIG. 7 is a schematic view illustrating a chuck unit according to the present disclosure.

FIG. 8 is a schematic view illustrating another chuck unit according to the present disclosure.

FIG. 9 is a schematic plan view illustrating another chuck unit according to the present disclosure.

FIG. 10 is a first cross-sectional view illustrating another chuck unit according to the present disclosure.

FIG. 11 is a second cross-sectional view illustrating another chuck unit according to the present disclosure.

FIG. 12 is a schematic view illustrating a guide plate according to the present disclosure.

FIG. 13 is a schematic view illustrating a transportation unit according to the present disclosure.

FIG. 14 is a schematic view illustrating a cross-section of transportation unit according to the present disclosure.

FIG. 15 is a schematic cross-sectional view illustrating a portion of a transportation unit according to the present disclosure.

FIG. 16 is a schematic view illustrating a deposition layer formed on a first substrate and a transportation unit according to the present disclosure.

FIG. 17 is a schematic view illustrating a deposition layer formed on a first substrate under an environment where a second carrier is applied according to the present disclosure.

FIG. 18 is a schematic view illustrating a state of deposition layer of a transportation unit according to the present disclosure.

FIG. 19 is a schematic view illustrating a plasma device including a transportation unit according to the present disclosure.

FIG. 20 is a schematic view illustrating a thermal conduction gas channel of FIG. 19.

FIG. 21 is a schematic view illustrating another chuck unit according to the present disclosure.

### DETAILED DESCRIPTION

Hereinafter, exemplary embodiments of the present disclosure will be described in detail with reference to the accompanying drawings. In describing the present disclosure, certain layers, sizes, shapes, components or features may be exaggerated for clarity and convenience. Accordingly, the meaning of specific terms or words used in the specification and claims should not be limited to the literal or commonly employed sense, but should be construed or may be different in accordance with the intention of a user or an operator and customary usages. Therefore, the definition of the specific terms or words should be based on the contents across the specification.

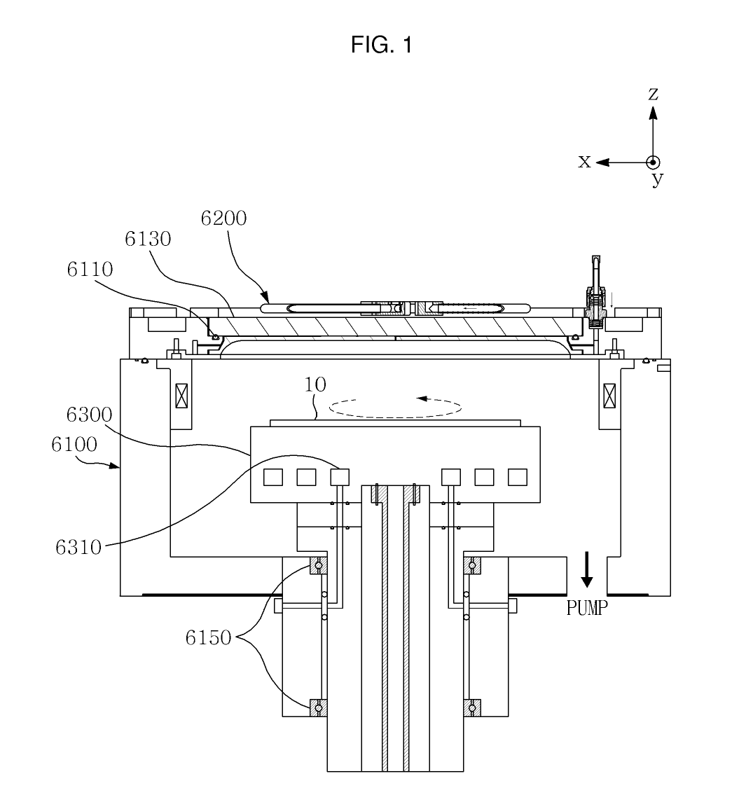

FIGS. 1 to 12 illustrate a plasma device according to a first exemplary embodiment of the present disclosure.

Now, referring to FIGS. 1 to 12, a plasma device according to a first exemplary embodiment of the present disclosure will be described in detail.

A plasma device according to a first exemplary embodiment of the present disclosure may include a chamber (6100), a plasma source (6200) and a chuck unit (6300).

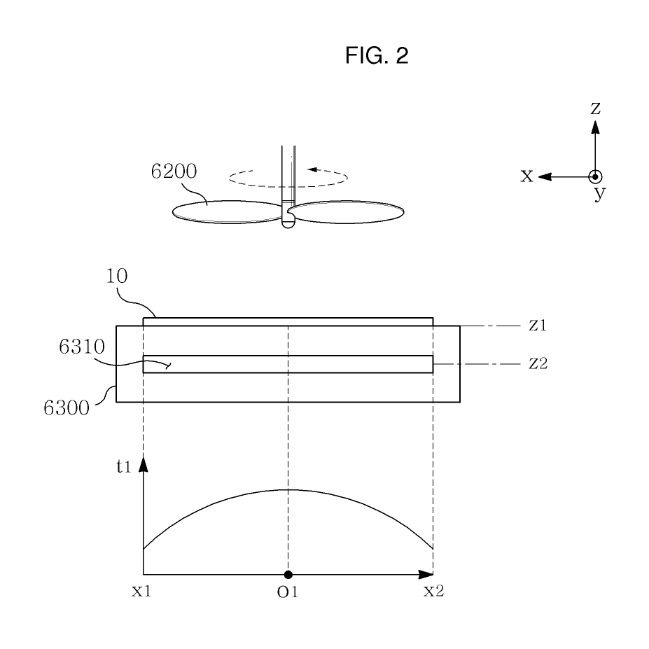

The chuck unit (6300), which is provided inside the chamber (6100), may mount or support a processed article (10) accommodated in the chamber (6100). Although FIG. 1 illustrates that the chuck unit (6300) is rotated by a bearing (6150) interposed between the chuck unit (6300) and the chamber (6100), FIG. 2 illustrates an example of the plasma source (6200) being rotated. However, even if the plasma source (6200) is evenly arranged, it is realistically difficult to evenly distribute the intensity of plasma. Likewise, even if the plasma source (6200) or the chuck unit (6300) is rotated, plasma processing is realized more at vicinity of a rotation center than at a vicinity of marginal area, whereby the processed article (10) may be heated unevenly.

Furthermore, an electrode configured to apply a DC (Direct Current) voltage may be provided at the chuck unit (6300) in order to apply an electrostatic force, where the electrostatic force can provide a force to restrict the processed article (10) to the chuck unit (6300). At this time, a position where the electrode is provided may be more heated than other positions by heat resistance.

Furthermore, the chuck unit (6300) may be applied with an RF power source, where the chuck unit (6300) may procure an easy generation of plasma within the chamber in association with the plasma source (6200), or pull the plasma generated inside the chamber toward a direction facing the chuck unit (6300). At this time, heat is likewise generated from the chuck unit (6300) by the RF power source, where the heat may be transmitted to the processed article (10).

The processed article (10) may be heated with a different temperature at each position or locally ruptured by the uneven plasma intensity, DC voltage or RF power source transmitted to the chuck unit (6300). Thus, there is a need to reduce the temperature of the processed article (10). To this end, a cooling channel (6310) for flowing cooling water may be provided inside the chuck unit (6300).

FIG. 2 illustrates the cooling channel (6310). The cooling water flowing along the cooling channel (6310) can cool the chuck unit (6300). Thus, the processed article (10) in contact with the chuck unit (6300) cooled by the cooling water can be also cooled. In order to efficiently cool the processed article (10), the cooling channel (6310) may be arranged on an imaginary surface parallel with the processed article (10). The processed article (10) arranged on each plane and the cooling channel (6310) may face each other on a broader area, whereby an entire surface of the chuck unit (6310) facing the processed article (10) may be evenly cooled by the cooling channel (6310).

Meantime, a temperature of a first position at the processed article (10) may be higher than that of the second position. According to the rotating plasma source (6200) of FIG. 2, linear velocity of the plasma source (6200) may increase from a center to a peripheral direction. The plasma intensity per unit area at vicinity of periphery may be weaker than that at vicinity of the center. As discussed above, a temperature t1 of the processed article (10) applied with plasma of different intensity may be high at a center o1, and decrease towards a periphery x1 or x2. At this time, o1 may be a first position and x1 or x2 may be a second position.

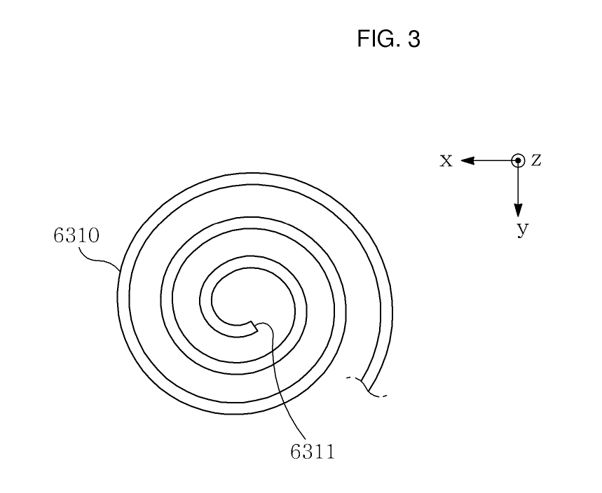

Referring to FIG. 3, the cooling channel (6310) may take a shape spirally extended from an inlet (6311) into which the cooling water is introduced from outside. The cooling water supplied from outside to the cooling channel (6310) may spirally flow along the cooling channel (6310) to absorb the heat of the processed article (10), whereby the temperature may increase. Thus, a cooling effect of the cooling water according to the spiral cooling channel (6310) may decrease in response to the spiral shape, and therefore, it is difficult to cool in a manner such that the temperature of the first position o1 and that of the second position x1 or x2 are same.

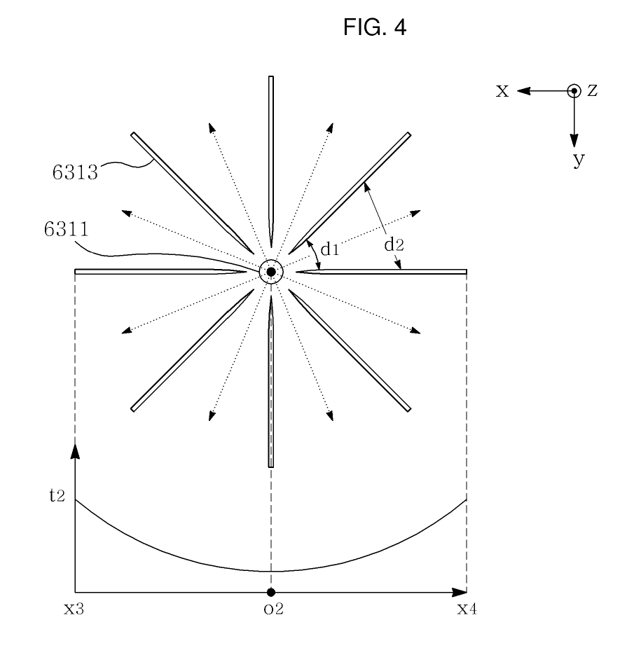

The cooling channel (6310) illustrated in FIG. 4 may be so configured as to allow the cooling water to flow about the inlet (6311) into which the cooling water is introduced from the outside. A temperature t2 of the cooling water may be lowest at a position o2 of the inlet (6311). Furthermore, the temperature of cooling water may increase due to absorption of surrounding heat as the cooling water flows towards x3 or x4 by a guide unit (6313).

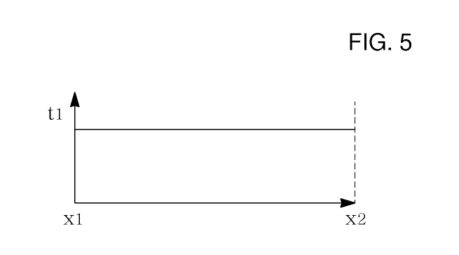

At this time, when the position o2 of the inlet (6311) is matched to o1 of FIG. 2 or x3 is matched to x1, or x4 is matched x2, when seen on a plane view, the temperature t1 of the processed article (10) may be constantly maintained irrespectively of the planar position. The graph in FIG. 5 may be viewed as a graph in which a graph of t1 in FIG. 2 and a graph of t2 in FIG. 4 are synthesized. To wrap up, the inlet (6311) of the cooling channel (6310) is preferably provided at the first position when seen on a plane view.

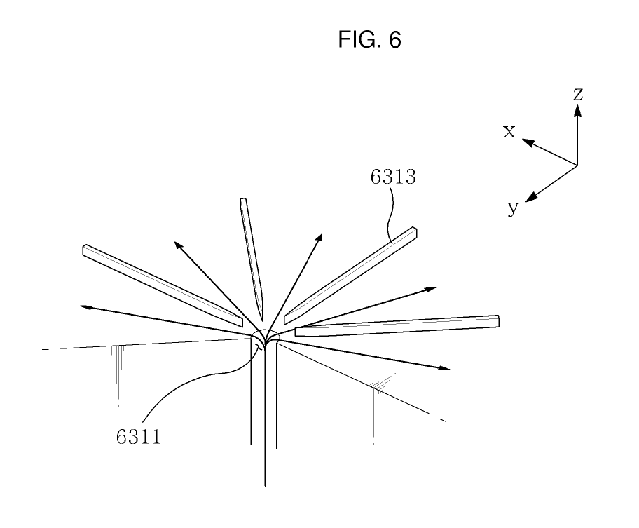

A guide unit (6313) may be provided at the cooling channel (6310) to guide the cooling water flowed through the inlet (6311) to flow toward the second position on a planar view. The guide unit (6313), as illustrated in FIG. 6, may include fins protruded from a surface formed with the inlet (6311) and extended to a radial direction.

Referring to FIG. 4 again, when the plasma source (6200) is rotated using the first position as a rotation shaft on a planar view, a center temperature of the processed article (10) corresponding to the first position on a planar view may be higher than a marginal or peripheral temperature corresponding to the second position. In this case, the guide unit (6313) may be radially extended about the inlet (6311) to allow the cooling water to radially flow toward a periphery from a center of the processed article (10). It should be apparent that the inlet (6311) of the cooling channel (6310) is preferably positioned on the first position on the planar view. Furthermore, the guide unit (6313) may be provided in a plural number.

At this time, a gap between each guide unit (6313) may gradually increase toward a radial direction. To be more specific, a distance d1 between two guide units (6313) mutually adjacent to the inlet (6311) may be smaller than a distance d2 between two guide units mutually adjacent to the periphery, whereby a cross-sectional area of channel may increase toward the radial direction. The cross-sectionally increased channel may be brought into contact with the broader area of the chuck unit (6300) to allow evenly cooling the chuck unit (6300). The cooling channel (6310) may be provided with an outlet (6318) from which the cooling water can be discharged to the outside. The cooling efficiency may be different in response to the position of the outlet (6318).

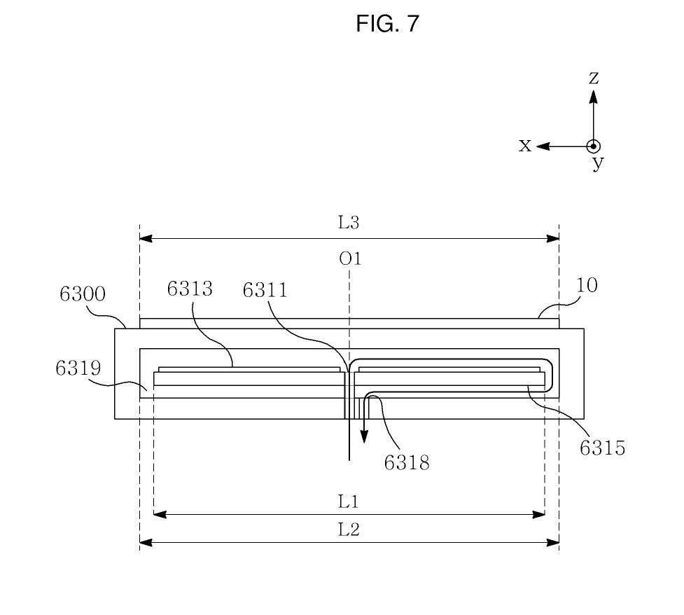

Referring to the chuck unit (6300) in FIG. 7, the cooling channel (6310) may be provided with a guide plate (6315) configured to guide flow of the cooling water in order to enhance the maximum cooling efficiency. A first surface of the guide plate (6315) facing the processed article (10) may be provided with an inlet (6311) configured to introduce the cooling water. The chuck unit (6300) may be provided with an accommodation space (6319) configured to accommodate the guide plate (6315). A surface (opposite surface of the first surface) facing a second surface of the guide plate (6315) at the accommodation space (6319) may be provided with an outlet (6318) configured to discharge the cooling water. At this time, an outer diameter L1 of the guide plate (6315) may be smaller than a minor diameter L2 of the accommodation space (6319). A first surface of the guide plate (6315) may be provided with a guide unit (6313) extended from the inlet (6311) toward a periphery of the guide plate (6315).

According to the configuration thus discussed, the cooling water outputted from the inlet (6311) may move toward the periphery of the guide plate (6315) along the first surface of the guide plate (6315) and the guide unit (6213). Furthermore, the cooling water having moved to the periphery of the guide plate (6315) may move to a second surface side of the guide plate (6315) through a gap formed by a difference between L1 and L2. Still furthermore, the cooling water having moved to the second surface side may move toward a center of the guide plate (6315) along the second surface of the guide plate (6315). At this time, the outlet (6318) may be formed at a center position of the guide plate (6315). Although it is preferable that the outlet (6318) be formed at a dead center of the guide plate (6315), the position of the outlet at the dead center may interfere with the inlet (6311). Thus, in order to prevent this occurrence, the outlet (6318) may be provided at a position maximally closer to the dead center while avoiding the interference with the inlet (6318).

To wrap up, the chuck unit (6300) may include a guide plate (6315) arranged inside the cooling channel (6310). At this time, the cooling water may be introduced into the inlet (6311) of the cooling channel, and flow to a radial direction of the guide plate (6315) along the first surface of the guide plate (6315). Furthermore, the cooling water may be changed in direction at the periphery of the guide plate (6315) and may flow to a central direction of the guide plate (6315) along the second surface of the guide plate (6315).

The second surface of the guide plate (6315) may be provided with a guide unit (6313). Furthermore, it is preferable that the minor diameter L2 of the accommodation space be greater than an outer diameter L3 of the processed article (10) in order to cool the processed article (10). Hence, according to the configuration thus discussed, a surface of the chuck unit (6300) opposite to the processed article (10) can be efficiently cooled.

A thermal conduction gas such as He capable of conducting heat may be filled in between the processed article (10) and the chuck unit (6300) in order to smoothly perform the thermal conduction between the chuck unit (6300) and the processed article (10). The thermal conduction gas can transmit the heat of high-temperatured state in the processed article (10) to the chuck unit (6300) of relatively low-temperatured state. The thermal conduction gas may be discharged through an outlet (6317) provided at a mounting surface opposite to the processed article (10) at the chuck unit (6300). The thermal conduction gas thus discharged may be dispersed to all directions along a rib or a gap artificially formed on the mounting surface.

Meantime, according to the rib formed at the mounting surface, the thermal conduction gas contacts only a portion of the processed article (10) opposite to the rib. As a result, the portion opposite to the rib at the processed article (10) may be concentratively cooled while the other portions are less cooled. As a result, the processed article (10) comes to have a different temperature at each portion, whereby the processed article (10) may be twisted, or there may be generated a rupture on the processed article (10). In order to solve the problem, it is preferable that the thermal conduction gas be evenly distributed on an entire surface of the processed article (10).

To this end, an entire mounting surface in the chuck unit (6300), on which the processed article (10) is mounted, may be naturally formed with a fine space (6316) by surface roughness inevitably formed at the time of mechanical engineering works such as cutting/milling works of the chuck unit (6300). The surface roughness of the mounting surface generated during the mechanical engineering works of the mounting surface of the chuck unit (6300) naturally forms the fine space (6316) on the mounting surface of the chuck unit (6300). The fine space (6316) may be filled with the thermal conduction gas configured to conduct the heat between the processed article (10) and the chuck unit (6300).

The surface roughness may be defined by size of roughness (unevenness, irregularities) having a short period and a relatively small irregular amplitude generated on a mechanically worked metal surface. The surface roughness may be measured by a stylus type measurement unit or an optical measurement unit. The surface roughness which is contour generated on a cross-section perpendicular to a measurement surface may be obtained by a cross-sectional curved line extensively recorded to a vertical or horizontal direction. A surface having a design dimension of the chuck unit (6300) including the mounting surface and tolerance may be defined as a nominal surface. At this time, a surface texture may be defined as a shape or a state of a surface including surface roughness observed when the nominal surface is measured.

As comparative exemplary embodiment, a method forming a gas moving space by forming a rib or a gap may be defined as roughness forming method of the nominal surface, whereas, because the natural fine space (6316) forming method by surface roughness according to the present disclosure is a gas moving space forming method by surface texture, the method according to the present disclosure is a micro dimensional space forming method over a gas channel formation intended during design. The gas moving space formation according to the surface texture of the present disclosure can guarantee a random sized micro space. Thus, in light of probability, the method according to the present disclosure has an advantage of obtaining a more uniform micro-sized fine space (6316).

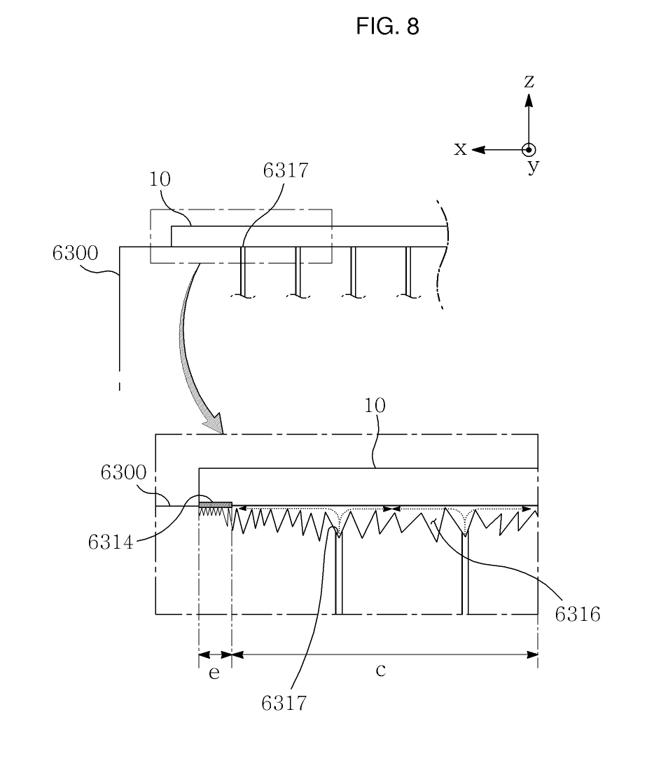

FIG. 8 illustrates a chuck unit (6300) having a gas moving space according to surface texture. It is assumed that an area mounted with the processed article (10) on a mounting surface of the chuck unit (6300) is called a mounting area (e+c).

The mounting area may include at least an outlet (6317) configured to discharge the thermal conduction gas and a fine space (6316) which may be a diffusion passage of the thermal conduction gas. Although FIG. 8 has illustrated the fine space (6316) in an exaggerated manner for convenience of explanation, the fine space (6316) has in fact a uniform space size of micro dimension. The fine space (6316) may be formed by surface roughness that remains after mechanical engineering works such as cutting and milling works.

The fine space (6316) formed by surface roughness may form complex passages randomly connected over an entire domain of the mounting area. According to random distribution of the fine space (6316), the thermal conduction gas outputted though the outlet (6317) may be evenly diffused across the entire domain through the fine space (6316) to allow the processed article (10) to be evenly cooled.

Meantime, when the fine space (6316) is formed across the entire domain of mounting area or an entire mounting surface, there is a possibility of the thermal conduction gas being discharged into the chamber (6100) by deviating from the mounting area, whereby there is a need of providing a means to prevent the thermal conduction gas from being discharged into the chamber (6300).

An external edge area of the processed article (10) may a dummy area not formed with a pattern. The edge area may be an area tangent to the dummy area of the processed article (10). A center area may be an area that excludes the edge area in the mounting area. The center area may be provided with at least one outlet (6317) of thermal conduction gas.

Although the edge area may be arranged with an O-ring to prevent the thermal conduction gas from being discharged into the chamber (6100) in the comparative exemplary embodiment, the O-ring may be stuck to the processed article (10) or to the O-ring due to high temperature. Thus, it is preferable that a more effective means than the O-ring be provided to lock up or store the thermal conduction gas between the processed article (10) and the chuck unit (6300).

For an example, when the mounting area is divided into an edge area e and a center area c, the fine space (6316) may be formed only in the center area. According to this configuration, the surface roughness of the edge area e may be smaller than that of the center area c. The fine space (6316) may have been formed to have a greater surface roughness through the roughness processing of the center area.

For an example, the surface roughness of the edge area e may be less than that of the processed article (10). Furthermore, the surface roughness of the center area c may be greater than that of the processed article (10), whereby a greater amount of thermal conduction gas may be distributed to the center area c to further enhance the gas closeness effect of the edge area e.

According to experiments, when the surface roughness at the edge area e is less than 0.8 S, and the surface roughness of center area c is 6.3 S˜12.6 S, it was noted that the thermal conduction effect by the thermal conduction gas and the closeness effect of the thermal conduction gas could be obtained.

Meantime, the edge area may be arranged with a closing (shutdown) film (6314). The closing film (6314) may include a polyamide excellent in heat resistance. Thus, the closing film (6314) can further prevent the thermal conduction gas from deviating from the mounting area. When the closing film (6314) is applied to the fine space (6316) and to the cooling channel (6310), the processed article (10) can be evenly cooled.

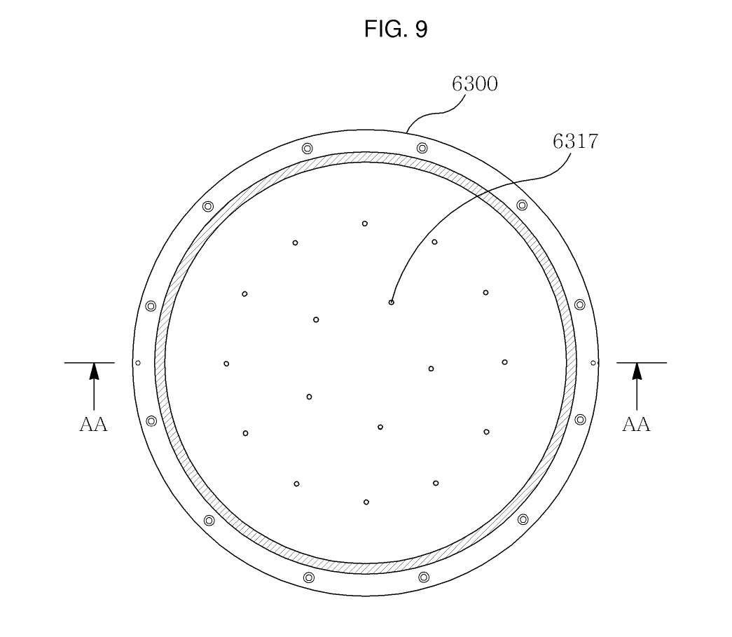

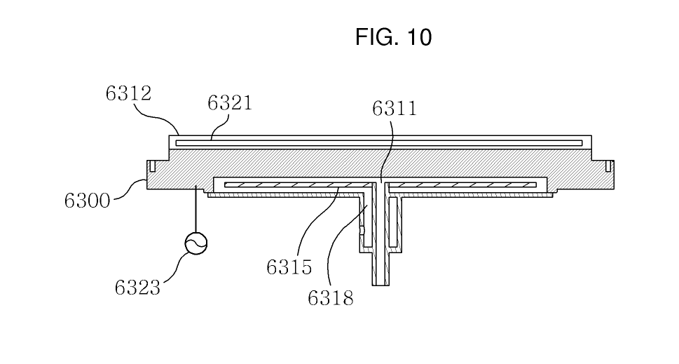

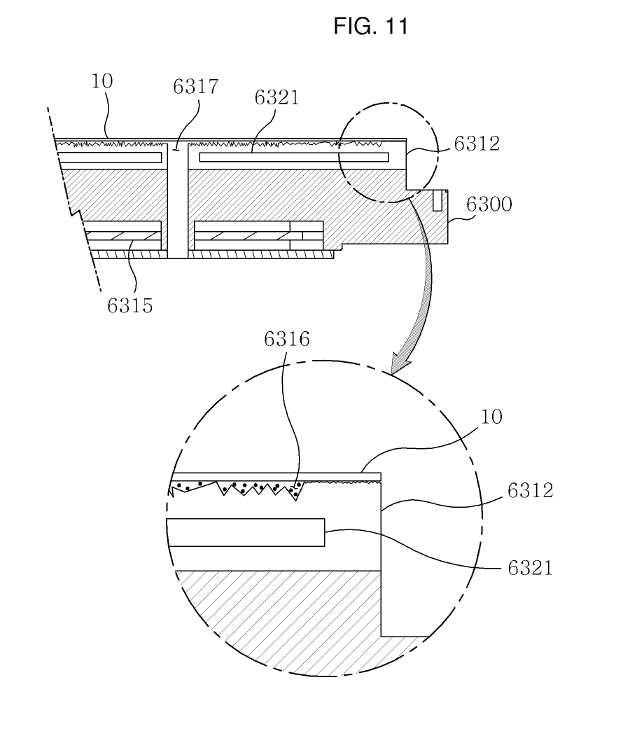

FIG. 10 is a first cross-sectional view of line AA-AA of FIG. 9, and FIG. 11 is a second cross-sectional view of another chuck unit according to the present disclosure.

FIGS. 9 to 11 disclose a chuck unit (6300) having a round shape when seen from a plane view.

A surface of the chuck unit (6300) opposite to the processed article (10) may be formed with an insulation layer (6312). Furthermore, the insulation layer (6312) may be provided with an electrode (6321) applied with a DC voltage. The relevant electrode (6321) may allow the processed article (10) mounted on the chuck unit (6300) to be absorbed into the chuck unit (6300) by generating electrostatic force. Furthermore, the chuck unit (6300) may be applied with an RF power source (6323). The RF power source (6323) may induce the plasma generated from inside the chamber (6100) to move toward the processed article (10) on the chuck unit (6300) in cooperation with the plasma source (6200).

One side of the electrode (6321) may be grounded to the chamber (6100), and the other side of the electrode (6321) may be rotatably connected to the chuck unit (6300). The other side of the electrode (6321) may be connected to a power source for applying an electrostatic force or the RF power source. Because the electric power must be supplied through the other side of the electrode (6321) even if the chuck unit (6300) is rotated, the other side of the electrode (6321) can be electrically connected and rotatably connected to the chuck unit (6300).

The inlet (6311) of the cooling channel (6310) may be provided at the center of the chuck unit (6300) when seen from a plane view, and outside cooling water can be supplied to the cooling channel (6310) through the relevant inlet (6311). The cooling water thus supplied may move to a direction facing the periphery of the chuck unit (6300) along the guide plate (6315), be changed in direction at a periphery of the guide plate (6315) and move toward the center of the chuck unit (6300).

The chuck unit (6300) may be provided with a passage configured to flow the thermal conduction gas. The relevant passage may be extended to the outlet (6317) of the mounting area by passing through the chuck unit (6300) and the guide plate (6315). The thermal conduction gas may be discharged while being absorbed with the processed article (10). The thermal conduction gas discharged through the outlet (6317) may be dispersed to all directions along the fine space (6316) formed at the mounting area.

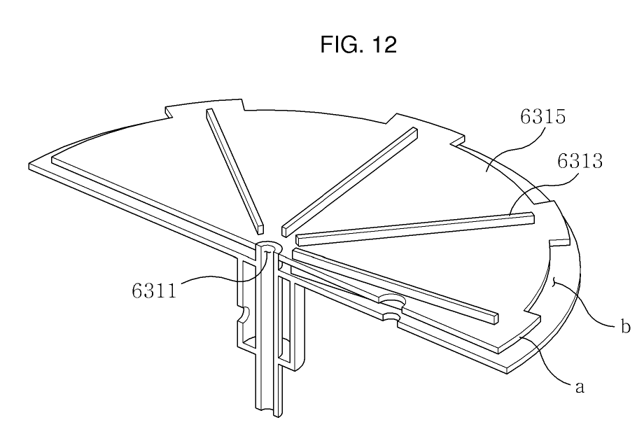

FIG. 12 illustrates a guide plate (63150. A diameter of the guide plate (6315) may be smaller than that of the accommodation space (6319). A periphery of the guide plate (6315) may be provided with a protruder \textcircled{a} protruded toward a direction facing an inner circumferential surface of the accommodation space (6319) in order to install the guide plate (6315) in the accommodation space (6319). The protruder \textcircled{a} may be coupled to an inner circumference of the accommodation space (6319).

The protruder \textcircled{a} may be provided in a plural number along a set gap \textcircled{b}. The thermal conduction gas can move toward the second surface from the first surface of the guide plate (6315) through a gap corresponding to the set gap \textcircled{b}.

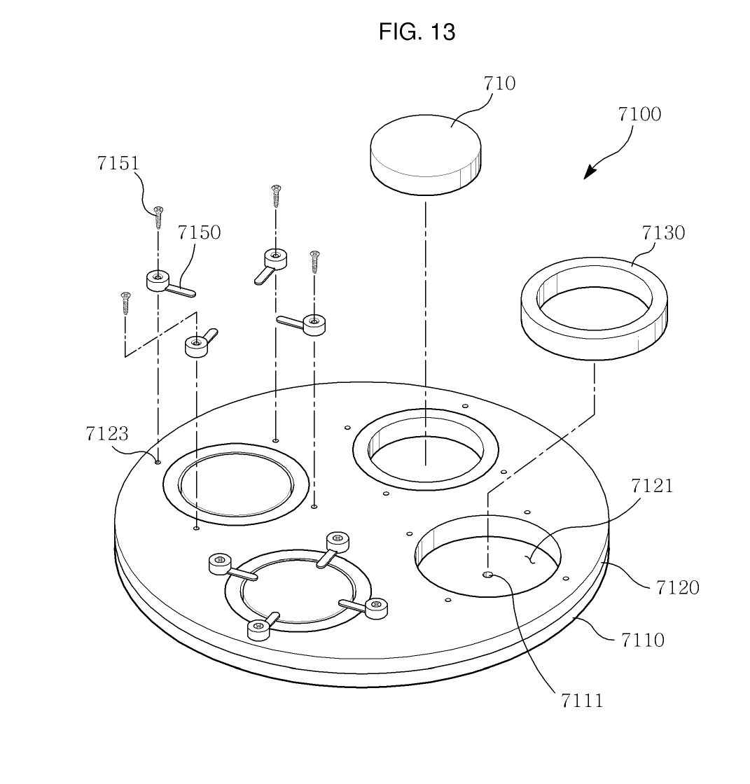

The characteristic configuration in FIGS. 13 to 21 is to illustrate a transportation unit useful to a first substrate including sapphire substrate or a small-sized substrate difficult to be applied with electrostatic chuck.

A transportation unit (7100) of FIG. 13 may be mounted or accommodated with a first substrate (710) plasma-processed by the chamber (7400). The transportation unit (7100) may move to a chuck unit (7300) along with the first substrate (710) and may be plasma-processed inside the chamber (7400) along with the first substrate (710). In general, the chuck unit (7300) may accommodate a second substrate (not shown) of substantially same size as that of the chuck unit (7300). It may be difficult to support using only the chuck unit (7300) when a plurality of first substrates (710) each having a size smaller than that of the second substrate is accommodated into the chamber (7400).

As discussed above, the transportation unit (7100) may be used to accommodate the particular first substrate (710) into the chuck unit (7300). To this end, the size of the transportation unit (7100) is preferably same as or greater than that of the conventional second substrate corresponding to the chuck unit (7300). When the size of the first substrate (710) is awfully smaller than that of the second substrate, the transportation unit (7100) may be accommodated with a plurality of first substrates (710).

Meantime, the transportation unit (7100) may function as a radiator in order to cool the first substrate (710). A thermal conduction medium may be interposed between the first substrate (710) and the transportation unit (7100) in order to efficiently transmit the heat of the first substrate (710) to the transportation unit (7100). The thermal conduction medium may be thermal conduction gas such as He that does not prevent the plasma treatment process.

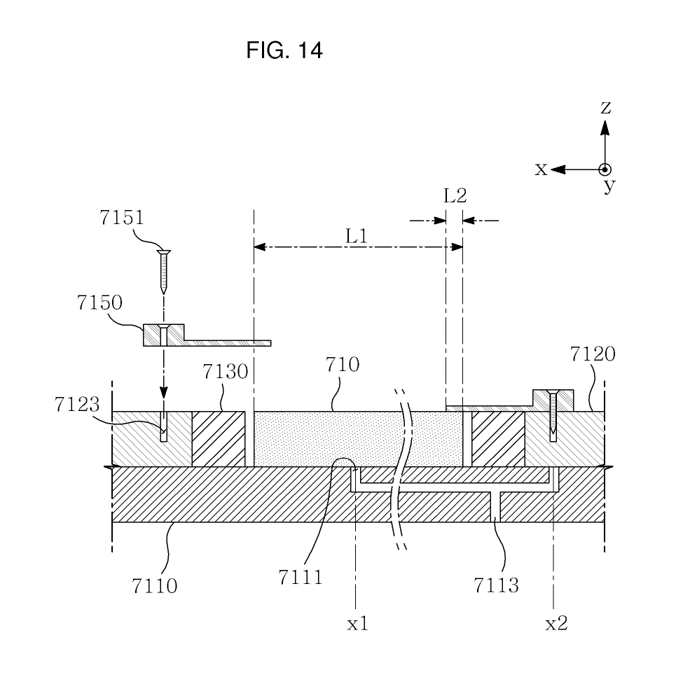

The transportation unit (7100) illustrated of cross-section thereof in FIG. 14 may be provided with a first outlet (7111) configured to discharge the thermal conduction gas configured to transport the heat of the first substrate (710) to the transportation unit (7100). The first substrate (710) may be floated from the transportation unit (7100) by the pressure of the thermal conduction gas discharged to the first outlet (7111).

The floated first substrate (710) may be deviated to another position by deviating from an initial position. In order to prevent this occurrence, pressure means for applying pressure to the first substrate (710) may be provided to a direction facing the transportation unit (7100). The pressure means may include a magnetic force member, an electrostatic force member or a clamp.

The magnetic force member may be realized by allowing the first substrate (710) and the transportation unit (7100) to include materials of different magnetic polarities. The electrostatic force member may be realized by allowing the first substrate (710) and the transportation unit (7100) to have mutually opposite electric charges. At this time, there may be generated a problem of not providing an electrostatic force if the first substrate (710) is a sapphire wafer. The clamp may mechanically depress the first substrate (710) to a direction facing the transportation unit (7100). However, there may be a problem of a portion shaded by the clamp not being plasma-processed due to a shadow effect in which a portion of the first substrate (710) is shaded by the clamp.

FIG. 14 discloses a first clamp (7150) as a means that applies pressure to the first substrate (710) to a direction facing the transportation unit (7100). The area shaded by the first clamp (7150) at the first substrate (710) cannot be plasma-processed, the phenomenon of which is called a shadow effect.

In order to maximally reduce the shadow effect, the first clamp (7150) may apply pressure to an edge of the first substrate (710), whereby the floatation (suspension) of the first substrate (710) by the thermal conduction gas may be restricted by the first clamp (7150). Although there is no way of avoiding the shadow effect by applying the first clamp (7150), a shadow effect area at this time is preferably minimized.

For example, when a diameter or a length of the first substrate (710) is L1, and an area in which the first clamp (7150) penetrates the first substrate (710) is L2, L1 is preferably greater by 20 times than L2. The shadow effect may be minimized by this configuration. Furthermore, when the L2 area in the first substrate (710) is a dummy area of no pattern, there would be almost no disadvantage due to the shadow effect.

Meanwhile, the first clamp (7150) may be also plasma-processed along with the first substrate (710) inside the chamber (7400). In case of deposition process, the first substrate (710) as well as the first clamp (7150) may be formed with a deposition layer (711). The deposition layer (711) may be in a state of being connected to the first substrate (710) and the first clamp (7150). Thus, a portion of the deposition layer (711) deposited on the first substrate (710) may be removed when the first clamp (7150) is torn off after plasma process.

In order to reduce this phenomenon, the first clamp (7150) may include a material same as that of the first substrate (710). When the material of the first clamp (7150) is same as that of the first substrate (710), the phenomenon of the deposition layer (711) being torn off during deviation of first clamp (7150) can be minimized.

Meantime, the first clamp (7150) may be coupled to the transportation unit (7100) by fastening screw (7151). The transportation unit (7100) may be provided with a first carrier (7110) mounted with the first substrate (710), a second carrier (7120) configured to cover the first carrier (7110) by avoiding the first substrate (710) and an edge ring (7130) configured to surround a lateral surface of the first substrate (710). At this time, a fastening hole (7123) fastened by the fastening screw (7151) may be provided on the second carrier (7120). The second carrier (7120) may be formed with an insertion hole (7121) passed by the first substrate (710).

The second carrier (7120) may be attachably and detachably mounted on the first carrier (7110), whereby various second carriers (7120) different in terms of position, size and the number of insertion holes (7121) may be installed on the first carrier (7110). As a result, various sizes of first substrates (710) may be accommodated in the transportation unit (7100).

Furthermore, a surface on the first carrier (7110) facing the insertion hole (7121) may be provided with a first outlet (7111) configured to discharge the thermal conduction gas. The insertion hole (7121) of the second carrier (7120) may be formed on a position including at least one of the plurality of first outlets (7111) on the first carrier (7110). The thermal conduction gas outputted from the first outlet (7111) provided on a position corresponding to that of the insertion hole (7121) may be interposed between the first substrate (710) inserted into the insertion hole (7121) and the first carrier (7110). At this time, the thermal conduction gas may transmit the heat of the first substrate (710) to the first carrier (7110).

Meantime, even if the thermal conduction gas does not exert a serious influence on the plasma processing, it would be troublesome if the thermal conduction gas is introduced into the chamber (7400) by deviating from the first carrier (710) and the first carrier (7110). In order to prevent this occurrence, an O-ring may be provided, but the O-ring may be stuck due to high temperature. Thus, seal means by surface roughness which is better than the O-ring according to the present disclosure will be explained hereunder.

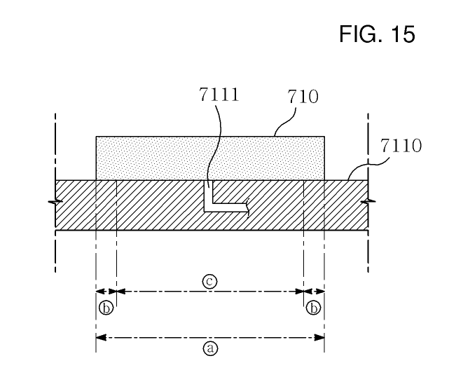

Referring to FIG. 15, the first carrier (7110) may include a mounting area \textcircled{a} mounted by the first substrate (710). The mounting area \textcircled{c} may be divided into a center area \textcircled{c} and an edge area \textcircled{b}. The center area \textcircled{c} may be a central area of the mounting area \textcircled{a}, while the edge area \textcircled{b} may be a marginal area excluding the center area \textcircled{c} in the mounting area \textcircled{a}.

The surface roughness of the edge area \textcircled{b} may be smaller than that of the center area \textcircled{c}. The meaning of the surface roughness being great is that a large quantity of thermal conduction gas may be distributed at the first substrate (710) mounted on the mounting area \textcircled{a}. The meaning of the surface roughness being small is that the thermal conduction gas may have a difficulty in passing through the edge area \textcircled{b}.

The center area \textcircled{c} may be positioned with at least one first outlet (7111). The edge area \textcircled{b} having a smaller surface roughness than the center area \textcircled{c} can prevent the thermal conduction gas from leaking, replacing the O-ring. Meantime, the surface roughness of edge area \textcircled{b} and center area \textcircled{c} may be preferably interrelated with the surface roughness of the first substrate (710). The surface roughness of the edge area \textcircled{b} may be less than that of the first substrate (710). Furthermore, the surface roughness of the center area \textcircled{c} may be greater than that of the first substrate (710), whereby a larger quantity of thermal conduction gas than that at the center area \textcircled{c} can be distributed to further enhance the gas closeness effect of edge area \textcircled{b}.

According to experiments, when the surface roughness at the edge area \textcircled{b} is less than 0.8 S, and the surface roughness of center area \textcircled{c} is 6.3 S˜12.6 S, it was noted that the thermal conduction effect by the thermal conduction gas and the closeness effect of the thermal conduction gas could be strongly demonstrated.

The foregoing discussion has explained that the deposition layer (711) deposited on the first substrate (710) may be torn apart by the deposition layer (711) deposited on the first clamp (7150), and this phenomenon may be generated on the first carrier (7110).

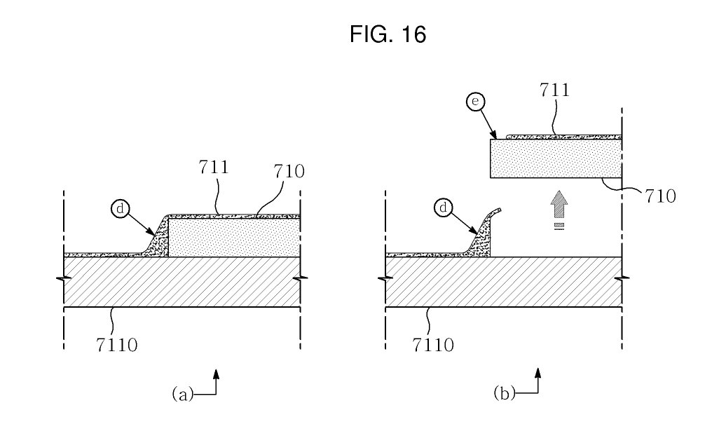

FIG. 16 is a schematic view illustrating a deposition layer (711) formed on a first substrate (710) and a transportation unit (7100) according to the present disclosure.

The first substrate (710) may be mounted on the first carrier (7110) of the transportation unit (7100). The first carrier (7110) is plasma-processed along with the first substrate (710) such that the deposition layer (711) may be also formed on the transportation unit (7100). At this time, a large quantity of deposition may be formed at a border area \textcircled{d} by a staircase between the first carrier (7110) and the first substrate (710) as shown in FIG. 16(a).

When the first substrate (710) is separated from the first carrier (7110) under this state as shown in FIG. 16(d), there is a high probability that the deposition layer (711) deposited on the first carrier (7110) may tear the mutually-connected deposition layer (711) of the first substrate (710). The reason is that, because the thickness of the deposition layer (711) at \textcircled{d} area is thicker than that of a normal deposition layer (711), there is a less probability of being first cut out when the first substrate (710) is reduced. A portion of the deposition layer (711) normally deposited on the first substrate (710) is cut out and torn apart.

Furthermore, the deposition layer (711) accumulated at a high height at \textcircled{d} area of the first carrier (7110) may distort a posture of newly mounted first substrate (710), which makes it difficult to normally deposit. A second carrier (7120) may be used in order to remove the deposition layer (711) accumulated at a high height at the border area \textcircled{d}.

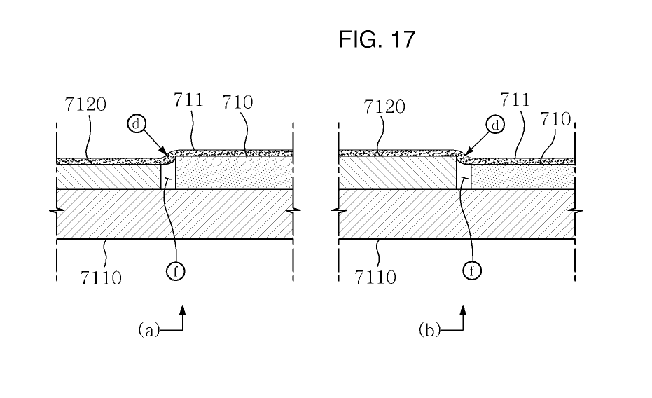

FIG. 17 is a schematic view illustrating a deposition layer formed on the first substrate (710) under an environment where the second carrier (7120) is applied according to the present disclosure.

The second carrier (7120) may be provided with an insertion hole (7121) corresponding to a through hole, into which the first substrate (710) may be inserted. The first substrate (710) thus inserted into the insertion hole (7121) may be mounted on the first carrier (7110). The second carrier (7120) formed with the insertion hole (7121) may have a smaller staircase with the first substrate (710) compared with the first carrier (7110).

For example, a height of the second carrier (7120) may be lower than the first substrate (710) as illustrated in FIG. 17(a), or higher than the first substrate (710) as shown in FIG. 17(b). However, the staircase with the first substrate (710) may be smaller compared with the first carrier (7110). According to the small staircase thus discussed, the deposition layer (711) may straddle at a gap portion \textcircled{f} between the first substrate (710) and the second carrier (7120) in the form of a leg by such phenomenon as surface tension. That is, a deposition layer (711) of a great thickness may not be formed at the border area \textcircled{d} of the first substrate (710).

As a result, the phenomenon of the deposition layer (711) of the first substrate (710) being torn apart can be reduced in the course of separating the first substrate (710) from the transportation unit (7100). Furthermore, the height of the first substrate (710) is preferably same as that of the second carrier (7120).

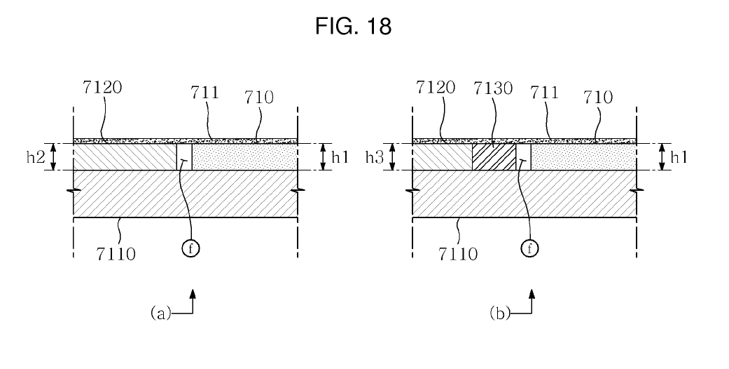

FIG. 18 is a schematic view illustrating a state of the deposition layer (711) being formed on a substrate jig according to the present disclosure.

Referring to FIG. 18(a), a first surface of the transportation unit (7100) may be provided with an insertion hole (7121) inserted by the first substrate (710). The transportation unit (7100) may be integrally formed, or as discussed in the foregoing, may include the first carrier (7110) and the second carrier (7120).

A height h1 of the first substrate (710) inserted into the insertion hole (7121) may be same as a height h2 of the first surface.

According to the configuration thus mentioned, the thickness of leg-shaped deposition layer (711) formed at a gap \textcircled{f} between the first substrate (710) and the second carrier (7120) can be minimized. As a result, the phenomenon of the deposition layer (711) deposited on the first substrate (710) being torn apart when the first substrate (710) is separated from the transportation unit (7100) can be prevented.

In order to further prevent the phenomenon of the deposition layer (711) deposited on the first substrate (710) being torn apart, like the first clamp (7150), the transportation unit (7100), particularly, the second carrier (7210) formed with the deposition layer (711) may include a same material as that of the first substrate (710). Meantime, there may be a case where it is difficult to make the second carrier (7120) have the same material as that of the first substrate (710).

For example, when the first substrate (710) is a sapphire wafer, it is very uneconomical to form an entire second carrier (7120) with a sapphire wafer. Furthermore, inconvenience may be expected where the second carrier (7120) must be changed to a relevant material, whenever material of the first substrate (710) is changed. In order to solve the aforementioned problem, the transportation unit (7100) may be provided with an edge ring (7130).

The edge ring (7130) may be attachably and detachably formed at an inner circumference of the insertion hole (7121) inserted by the first substrate (710). A minor diameter of the edge ring (7130) may be greater than an outer diameter of the first substrate (710). The edge ring (7130) has a very small volume compared with the second carrier (7120), such that there is no big difficulty in forming the material same as that of the first substrate (710). Furthermore, the second carrier (7120) may be used without any change, because the only thing is that the edge ring (7130) having a relevant material is changed and installed whenever material of the first substrate (710) is changed. At this time, the height h1 of the first substrate (710) inserted into the insertion hole (7121) may be same as a height h3 of the edge ring (7130) as illustrated in FIG. 18(b).

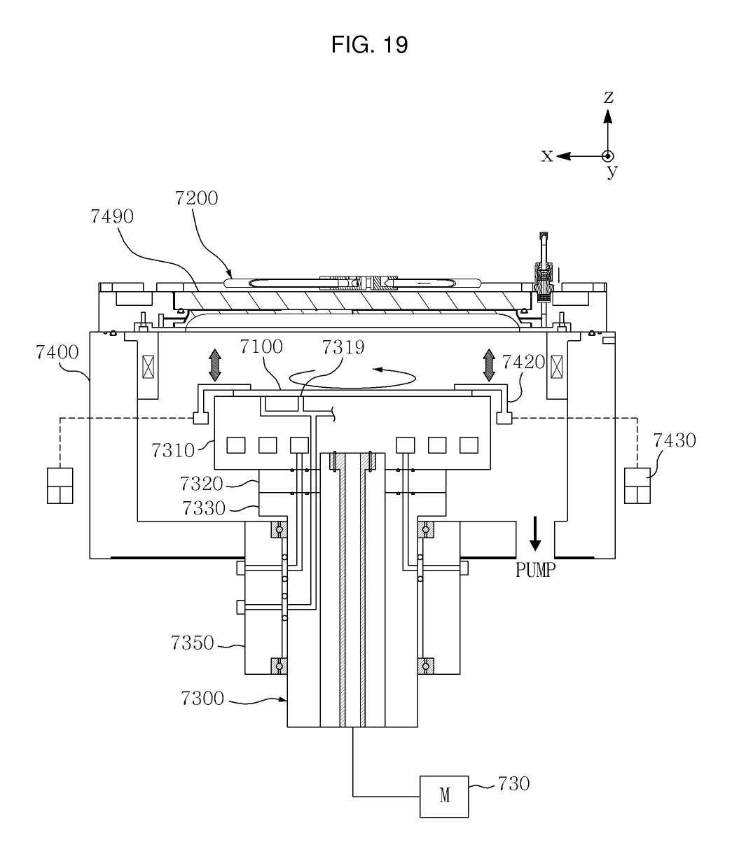

Referring to FIG. 19, the plasma device according to the present disclosure may include a transportation unit (7400), a plasma source (7200) and a chuck unit (7300). The transportation unit (7100) placed on the chuck unit (7300) may be accommodated with a first substrate (710). The plasma source (7200) is rotatable because of being provided at an upper surface of the chamber (7400). As an exemplary embodiment (not shown), the plasma source (7200) may be exemplarily inserted into the chamber (7400). The chuck unit (7300) may include a mounting unit (7310) mounted with the transportation unit (7100), and an axial unit (7330) configured to support the mounting unit (7310). In order to allow the plasma processing to be evenly performed inside the chamber (7400), the axial unit (7330) may rotate the mounting unit (7310) depending on cases.

A harmonics power source applied to the mounting unit (7310) through the axial unit (7330) may generate harmonics on the mounting unit (7310) to pull the plasma formed at an upper surface of the chamber (7400) by the plasma source (7200) to a direction facing the mounting unit (7310), whereby the plasma is accelerated and the force therefrom may process the surface of the first substrate (710).

The cooling water supplied to the mounting unit (7310) through the axial unit (7330) may cool the mounting unit (7310). A thermal conduction medium applied to the mounting unit (7310) through the axial unit (7330) may fill a fine gap formed between the mounting unit (7310) and the transportation unit (7100) and conduct the heat between the mounting unit (7310) and the transportation unit (7100). As a result, when the mounting unit (7310) is cooled by the cooling water, the transportation unit (7100) may be cooled through the thermal conduction medium. When the transportation unit (7100) is cooled, the first substrate (710) to which heat is conducted by the thermal conduction gas may be also cooled.

The plasma device according to the present disclosure may include a second clamp (7420) applying a pressure to the transportation unit (7100) to a direction facing the chuck unit (7300) and an actuator (7430) configured to move the second clamp (7420).

A surface on the chuck unit (7300) opposite to the transportation unit (7100) may be provided with a second outlet (7319) configured to discharge the thermal conduction gas such as Helium. The transportation unit (7100) may float from the chuck unit (7300) by the thermal conduction gas discharged through the second outlet (7319). At this time, the floatation of the transportation unit (7100) may be restricted by the second clamp (7420).

In general, the size of the substrate plasma-processed in a relevant chamber (7400) may be restricted by a gap of a plurality of second clamps (7420) inside the chamber (7400). Thus, the first substrate (710) having a size smaller than the gap of the second clamp (7420) is not applied with pressure by the second clamp (7420), and therefore, may be floated by the thermal conduction gas discharged from the chuck unit (7300).

When the transportation unit (7100) formed to match a gap of the second clamp (7420) is prepared, a plurality of chambers (7400) of various sizes can be plasma-processed.

The transportation unit (7100) may be provided with a first carrier (7110) mounted with the first substrate (710) and a first clamp (7150) configured to apply a pressure to the first substrate (710) to a direction facing the first carrier (7110). At this time, a surface of the first carrier (7110) facing the chuck unit (7300) may be provided with a first inlet (7113) into which the thermal conduction gas discharged to the second outlet (7319) is inputted.

Furthermore, a surface of the first carrier (7110) facing the first substrate (710) may be provided with a first outlet (7111) configured to discharge the thermal conduction gas inputted to the first inlet (7113). At this time, the first clamp (7150) may restrict the first substrate (710) from floating from the first carrier (7110) by the thermal conduction gas outputted through the first inlet (7110).

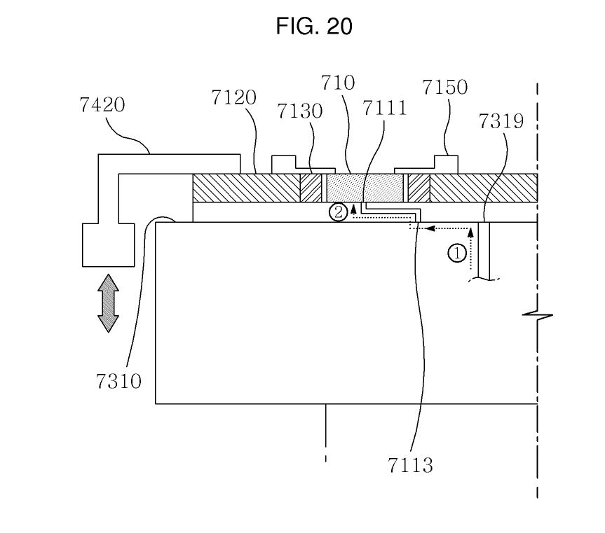

The thermal conduction gas of FIG. 20 is discharged through the second outlet (7319) provided at the chuck unit (7300) as in \textcircled{1} to be distributed between the chuck unit (7319) and the transportation unit (7100). At this time, the transportation unit (7100) may be lifted up by the thermal conduction gas, the phenomenon of which can be prevented by the second clamp (7420).

The thermal conduction gas thus dispersed to all directions may be introduced into the transportation unit (7100), to be more specific, to the first inlet (7113) provided at a bottom surface of the first carrier (7110). The thermal conduction gas introduced into the first inlet (7113) may move along a passage formed inside the first carrier (7110), and may be outputted through the first outlet (7111) provided at an upper surface of the first carrier (7110) as in \textcircled{2}. The thermal conduction gas thus outputted through the first outlet (7111) may be distributed between the first carrier (7110) and the first substrate (710) to push up the first substrate (710). The phenomenon of the first substrate (710) being pushed by the thermal conduction gas may be restricted by the first clamp (7150).

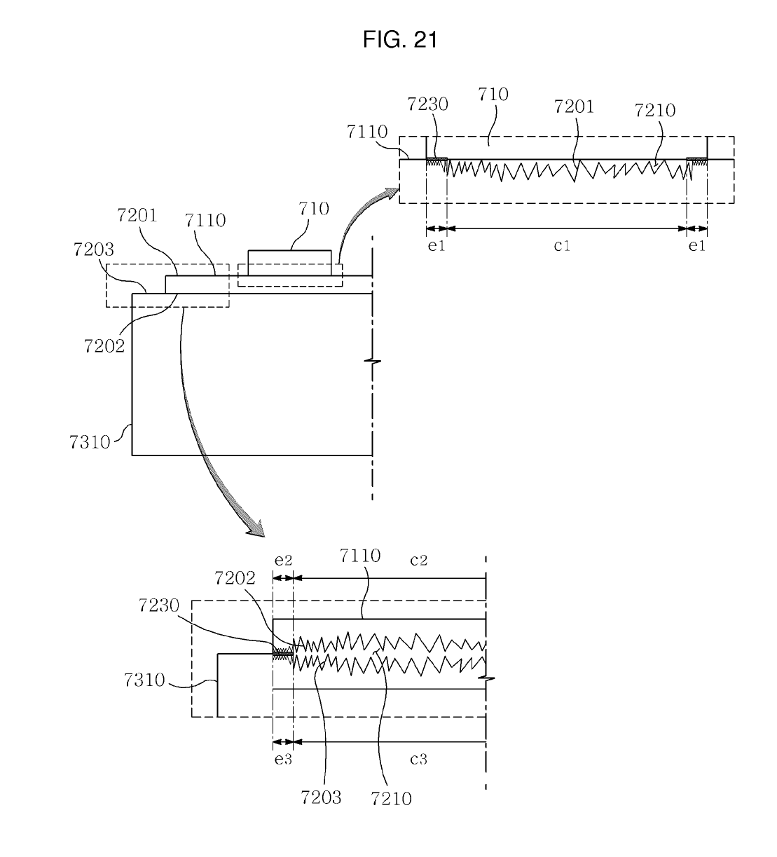

Referring to FIG. 21, the plasma device according to the present disclosure may include a transportation unit (7100) and a chuck unit (7300). A fine space (7210) naturally formed by surface roughness may be provided on at least one of a first surface (7201), a second surface (7202) and a third surface (7203).

The first surface (7201) may be a surface facing the first substrate (710) at the transportation unit (7100). The second surface (7202) may be a surface facing the chuck unit (7300) at the transportation unit (7100). The third surface (7203) may be a surface facing the transportation unit (7100) at the chuck unit (7300).

The fine space (7210) may be formed at each surface (7201, 7202, 7203) by the surface roughness naturally formed in the course of mechanical processing such as cutting, milling or the like. Although the fine space (7210) is illustrated in an exaggerated manner in FIG. 21 for the convenience of explanation, the fine space (7210) may be actually of a micro size.

According to the fine space (7210), the thermal conduction gas introduced between the first carrier (7110) and the mounting unit (7310) through a passage of \textcircled{1} in FIG. 20 may be easily dispersed to an entire area scope of the first carrier (7110) through the fine space (7210). To this end, at least one of the surfaces, the second surface (7202) and the third surface (7203) is preferably formed with the fine space (7210).

Furthermore, the thermal conduction gas introduced between the transportation unit (7100) and the first substrate (710) through a passage of \textcircled{2} in FIG. 20 may be easily dispersed to an entire area scope of the first carrier (7110) through the fine space (7210). To this end, the first surface (7201) may be formed with the fine space (7210).

Meantime, according to the fine space (7210) formed at each surface, the thermal conduction gas may be discharged by deviating from between the first substrate (710) and the transportation unit (7100) and from between the transportation unit (7100) and the chuck unit (7300). In order to prevent the thermal conduction gas from discharging, each surface may be given a different surface roughness at each area.

For example, the surface roughness at a first edge area eI of the first surface (7201) tangent to the first substrate (7201) may be smaller than that of a first center area cI tangent to the first substrate (710). The first edge area eI is a marginal area of the first substrate (710), and the first center area cI may be an area where almost no fine space (7210) is generated, or may have a surface roughness formed with a fine space (7210) of a size smaller than a particle size of the thermal conduction gas. As a result, the thermal conduction gas dispersed along the fine space (7210) formed at the center area cI cannot be discharged to the outside because of being blocked by the first edge area eI.

Similarly, a surface roughness of a second edge area e2 tangent to the chuck unit (7300) at the second surface (7202) may be smaller than that of a second center area c2 tangent to the chuck unit (7300). The second edge area e2 may be a marginal area of the transportation unit (7100), and the second center area c2 may be a central area of the transportation unit (7100).

Likewise, a surface roughness of a third edge area e3 tangent to the transportation unit (7100) at the third surface (7203) may be smaller than that of a third center area c3 tangent to the transportation unit (7100). The only difference between the second edge area e2 and the third edge area e3 is that the second edge area e2 is formed on the second surface and the third edge area e3 is formed on the third surface in terms of a formed surface, and therefore, may be same on a planar coordinate. The same principle is applied to the second center area c2 and to the third center area c3.

The thermal conduction gas introduced to between the transportation unit (7100) and the chuck unit (7300) cannot be discharged to the outside because of being blocked by the second edge area e2 or the third edge area e3. As another measure to prevent the thermal conduction gas from being discharged to the outside, at least one of the first edge area eI, the second edge area e2 and the third edge area e3 may be arranged with a closeness film (7230).

The closeness film (7230) may take a peripheral shape of the first substrate (710) or a peripheral shape of the transportation unit (7100) when seen from a plane view. Furthermore, a region corresponding to each center area may be formed with an opened circular shape. A flexible polyamide film excellent in heat resistance may be used for the closeness film (7230).

Depending on flexible properties of the closeness film (7230), the first edge area eI of the first substrate (710) and the transportation unit (7100), the second edge area e2 or the third edge area e3 of the transportation unit (7100) and the chuck unit (7300) may be removed of air gap or the fine space (7210), whereby the thermal conduction gas can be positioned at each center area instead of being deviated from each edge area.

When the configuration of providing the naturally generated fine space according to the surface roughness and the configuration of closeness film (7230) are combined, cooling property and shielding property of thermal conduction gas may be further enhanced.

Although the present disclosure has been described in detail with reference to the foregoing embodiments and advantages, many alternatives, modifications, and variations will be apparent to those skilled in the art within the metes and bounds of the claims. Therefore, it should be understood that the above-described embodiments are not limited by any of the details of the foregoing description, unless otherwise specified, but rather should be construed broadly within the scope as defined in the appended claims

What is claimed is:

1. A plasma device, the plasma device comprising:
a chamber configured to accommodate a processed article;
a plasma source configured to generate a plasma applied to the processed article accommodated in the chamber;
a chuck unit configured to support the processed article accommodated in the chamber; and
a cooling channel formed inside the chamber to allow flowing cooling water.

2. The plasma device of claim 1, wherein the chuck unit includes a guide plate arranged at an inner side of the cooling channel, wherein the cooling water is introduced into the cooling channel to flow to a radial direction of the guide plate along a first surface of the guide plate, and changed in direction at a periphery of the guide plate to flow a central direction of the guide plate along a second surface of the guide plate.

3. The plasma device of claim 1, wherein a temperature of a first position at the processed article grows higher than that of a second position by plasma processing, an inlet of the cooling channel is provided at the first position when viewed from a plan, and a guide unit is provided at the cooling channel to allow the cooling water introduced through the inlet to flow toward the second position when viewed from a plan.

4. The plasma device of claim 1, wherein the cooling channel includes an inlet formed at the first position to allow the cooling water to flow, and a plurality of radially extended guide units about the inlet, wherein the cooling water introduced into the inlet is flown to a radial direction by the guide unit.

5. The plasma device of claim 1, wherein the cooling channel is provided with a radially extended plurality of guide units, where each gap of the plurality of guide units gradually increases toward the radial direction.

6. The plasma device of claim 1, wherein the cooling channel is provided with a guide plate configured to guide flow of the cooling water, and the chuck unit is provided with an accommodation space configured to accommodate the guide plate, an outer diameter of the guide plate is smaller than a minor diameter of the accommodation space, the first surface of the guide plate opposite to the substrate is provided with an inlet configured to introduce the cooling water, and a surface of the accommodation space opposite to the second surface of the guide plate is provided with an outlet configured to discharge the cooling water.

7. The plasma device of claim 1, wherein a mounting surface configured to mount the processed article on the chuck unit is provided with a fine space naturally formed by a surface roughness, where the fine space is filled with thermal conduction gas configured to conduct heat between the processed article and the chuck unit.

8. The plasma device of claim 1, wherein a mounting area of the mounting surface mounted with the processed article is divided into an edge area and a center area, where surface roughness of the edge area is smaller than that of the center area.

9. The plasma device of claim 1, further comprising a closed film arranged at the mounting area of mounting surface mounted with the processed article to prevent the thermal conduction gas from deviating from the mounting area.

10. The plasma device of claim 1, wherein the chuck unit is provided with an electrode configured to apply electromagnetic force or an RF power source, one side of the electrode is grounded to a chamber and the other side of the electrode is rotatably connected to the chuck unit, and the other side of the electrode is connected with a power source for apply the electromagnetic force or the RF power source.

11. The plasma device of claim 1, wherein the chamber includes a transportation unit configured to accommodate a plasma-processed first substrate, and the transportation unit is plasma-processed in the chamber with the first substrate.

12. The plasma device of claim 11, wherein the first substrate has a first size, the chuck unit accommodates a second substrate, which is a processed article, has a second size, where the second size is greater than the first size, the size of the transportation unit is greater than that of the second substrate, and the transportation unit or the second substrate is accommodated into the chuck unit.

13. The plasma device of claim 11, wherein the transportation unit is provided with a first outlet configured to discharge the thermal conduction gas transmitting the heat of the first substrate to the transportation unit, and a first clamp configured to apply pressure to the first substrate to a direction facing the transportation unit, and the thermal conduction gas discharged from the outlet floats the first substrate from the transportation unit, and the first clamp applies a pressure to an edge of the first substrate and limits the floatation of the first substrate.

14. The plasma device of claim 11, wherein the transportation unit is provided with a first carrier configured to mount the first substrate, and a second carrier formed with an insertion hole passed by the first substrate and stacked with the first carrier, and a surface of the first carrier opposite to the insertion hole is provided with a first outlet configured to discharge the thermal conduction gas.

15. The plasma device of claim 11, wherein the transportation unit is provided with a first carrier having a mounting area to mount the first substrate, where the surface roughness of the edge area in the mounting area is smaller than that of the center area, and the first outlet is positioned at the center area.

16. The plasma device of claim 11, wherein a first surface of the transportation unit is provided with an insertion hole inserted by the first substrate, and a height of the first substrate inserted into the insertion hole is equal to that of the first surface.

17. The plasma device of claim 11, wherein the transportation unit is provided with an insertion hole inserted by the first substrate, and an edge ring attached to and detached from an inner circumference of the insertion hole, where the edge ring is made of a material same as that of the first substrate.

18. The plasma device of claim 11, wherein the transportation unit is provided with a mounting area mounted with the first substrate, and the surface roughness of the edge area in the mounting area is smaller than that of the center area.

19. The plasma device of claim 11, further comprising a second clamp configured to apply a pressure to the transportation unit to a direction facing the chuck unit, a surface opposite to the transportation unit in the chuck unit is provided with a second outlet configured to discharge the thermal conduction gas, where the second clamp prevents the transportation unit from floating from the chuck unit by the thermal conduction gas.

20. The plasma device of claim 11, wherein at least one of the first surface opposite to the first substrate in the transportation unit, the second surface opposite to the chuck unit in the transportation unit and the third surface opposite to the transportation unit in the chuck unit is provided with a fine space formed by the surface roughness after mechanical processing.
